(19) United States
(12) Patent Application Publication
(10) Pub. No.: US 2016/0126387 A1
(43) Pub. Date: May 5, 2016

(54) SOLAR CELL MODULE

(71) Applicant: Panasonic Intellectual Property Management Co., Ltd., Osaka (JP)

(72) Inventors: Haruhisa HASHIMOTO, Osaka (JP); Tasuku ISHIGURO, Osaka (JP); Naoto IMADA, Tokyo (JP)

(73) Assignee: Panasonic Intellectual Property Management Co., Ltd., Osaka (JP)

(21) Appl. No.: 14/996,730

(22) Filed: Jan. 15, 2016

Related U.S. Application Data
(63) Continuation of application No. PCT/JP2014/067366, filed on Jun. 30, 2014.

(30) Foreign Application Priority Data
Jul. 19, 2013 (JP) 2013-150027

(51) Int. Cl. H01L 31/05; H01L 31/02; H01L 31/0224

(52) U.S. Cl. CPC H01L 31/0504; H01L 31/022433; H01L 31/0201

(57) ABSTRACT

A solar cell module includes solar cells, each including a first bus bar electrode provided on a first principal surface and a second bus bar electrode provided on a second principal surface; a wiring member connecting the first bus bar electrode of one of adjacent two solar cells and the second bus bar electrode of the other solar cell; and a resin adhesive layer connecting the wiring member and any one of the first bus bar electrode and the second bus bar electrode. A distance between an end portion of the resin adhesive layer on the adjacent side and an end portion, on the adjacent side, of the solar cell provided with the resin adhesive layer is longer than a distance between the end portion of the solar cell and an end portion of the adjacent solar cell.

### CROSS REFERENCE TO RELATED APPLICATIONS

This application is a continuation application of PCT/JP2014/067366, filed on Jun. 30, 2014, which claims priority from prior Japanese Patent Applications No. 2013-150027, filed on Jul. 19, 2013, entitled “SOLAR CELL MODULE”, the entire contents of which are incorporated herein by reference.

### TECHNICAL FIELD

This disclosure relates to a solar cell module.

### BACKGROUND ART

A solar cell module is generally formed by arraying solar cell strings in each of which solar cells are arrayed and electrically connected to each other by wiring members. Electrodes of each of the solar cells and the wiring members are electrically connected through a resin adhesive layer such as a conductive adhesive layer, for example (Patent Document 1 and the like).

When a temperature cycle test (e.g., a cycle test of −40° C. to 90° C.) is conducted on such a solar cell module, wiring members may have cracks, breakage and the like, leading to poor connection.

Patent Document 1: Japanese Patent Application Publication No. 2009-231813

### SUMMARY OF THE INVENTION

It is an object of an embodiment of the invention to provide a solar cell module capable of suppressing occurrence of cracks, breakage and the like in a wiring member due to temperature change.

A solar cell module according to an aspect of the invention includes: solar cells, each including a first bus bar electrode provided on a first principal surface and a second bus bar electrode provided on a second principal surface; a wiring member provided for each adjacent two of the solar cells, and connecting the first bus bar electrode of one of the two solar cells and the second bus bar electrode of the other solar cell; and a resin adhesive layer connecting the wiring member and any one of the first bus bar electrode and the second bus bar electrode. A distance between an end portion of the resin adhesive layer on the adjacent side and an end portion, on the adjacent side, of the solar cell provided with the resin adhesive layer is longer than a distance between the end portion of the solar cell and an end portion of the adjacent solar cell.

The aspect of the invention makes it possible to suppress occurrence of cracks, breakage and the like in a wiring member due to temperature change.

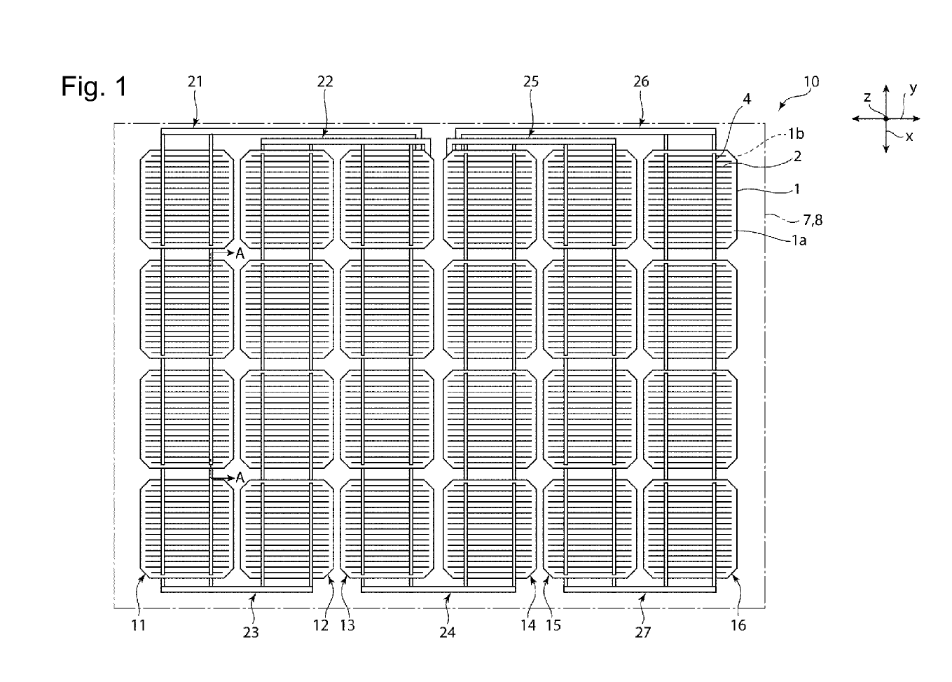

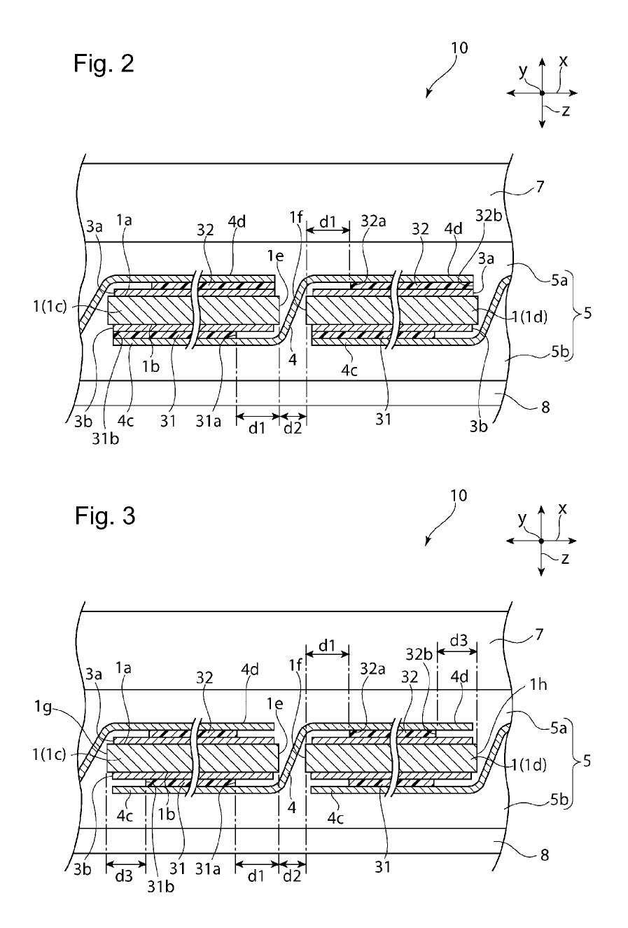

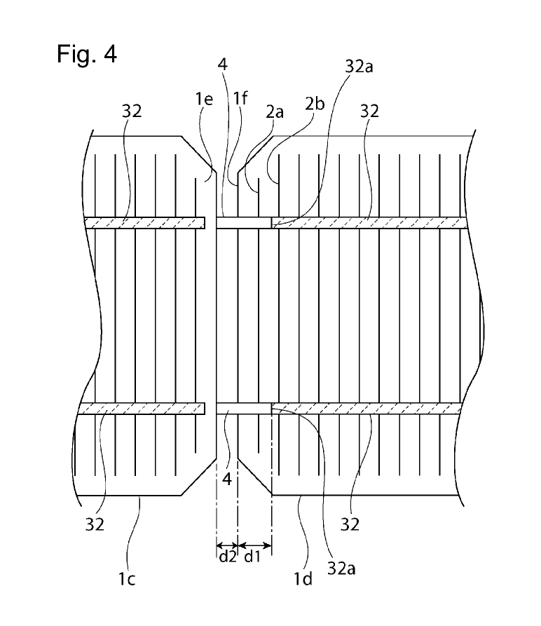

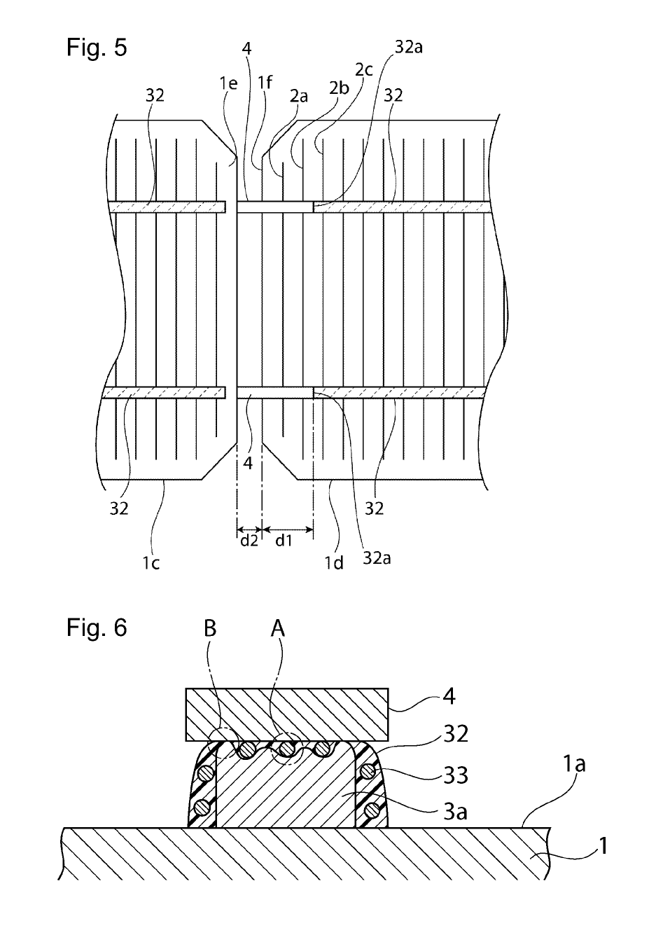

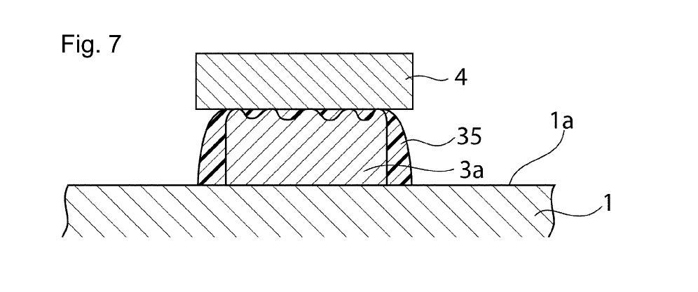

### BRIEF DESCRIPTION OF THE DRAWINGS

[FIG. 1] FIG. 1 is a schematic plan view illustrating a solar cell module according to a first embodiment.

[FIG. 2] FIG. 2 is a schematic cross-sectional view taken along the line A-A in FIG. 1, illustrating the solar cell module according to the first embodiment.

[FIG. 3] FIG. 3 is a schematic cross-sectional view illustrating a solar cell module according to a second embodiment.

[FIG. 4] FIG. 4 is a schematic plan view illustrating a solar cell module according to a third embodiment.

[FIG. 5] FIG. 5 is a schematic plan view illustrating a solar cell module according to a fourth embodiment.

[FIG. 6] FIG. 6 is a schematic cross-sectional view illustrating a connection state through a resin adhesive layer in the first to fourth embodiments.

[FIG. 7] FIG. 7 is a schematic cross-sectional view illustrating a connection state through a resin adhesive layer in another embodiment.

### MODES FOR CARRYING OUT THE INVENTION

Hereinafter, preferred embodiments are described. Note that the following embodiments are provided herein for illustrative purpose only, and the invention is not limited to the following embodiments. Moreover, in the following drawings, members having substantially the same functions may be denoted by the same reference numerals.

### First Embodiment

FIG. 1 is a schematic plan view illustrating a solar cell module according to a first embodiment. As illustrated in FIG. 1, solar cell module 10 includes solar cell strings 11 to 16 arrayed in a second direction (y direction). Solar cell strings 11 to 16 are formed by electrically connecting solar cells 1 arrayed in a first direction (x direction). Note that, in the invention, the “first direction” means a direction in which solar cells 1 are arrayed within solar cell strings 11 to 16. Meanwhile, the “second direction” means a direction in which solar cell strings 11 to 16 are arrayed, that is, a direction approximately perpendicular to the first direction.

On front surface 1a of each of solar cells 1, a number of finger electrodes 2 extending in the second direction are formed. Also, bus bar electrodes extending in a direction approximately orthogonal to finger electrodes 2 are provided so as to be electrically connected to finger electrodes 2. Moreover, although not illustrated in FIG. 1, finger electrodes 2 and bus bar electrodes are also formed on back surface 1b of solar cell 1, as in the case of front surface 1a. Note that finger electrodes 2 formed on back surface 1b are formed more densely than those formed on front surface 1a. Finger electrodes 2 and the bus bar electrodes formed on back surface 1b constitute a back surface electrode of solar cell 1.

FIG. 1 illustrates the bus bar electrodes on front surface 1a covered with wiring members 4. Thus, the bus bar electrodes on front surface 1a are provided to extend in the first direction of solar cell 1. Note that the extending direction of the bus bar electrodes is not limited to a direction along a straight line parallel to the first direction. For example, the bus bar electrodes may extend in a zigzag pattern in which straight lines non-parallel to the first direction are connected one to another.

As illustrated in FIG. 1, wiring members 4 provided on the front surface 1a side of top solar cell 1 in solar cell string 11 are connected to first interconnection wiring member 21. Wiring members 4 provided on the back surface 1b side of the bottom solar cell 1 in solar cell string 11 are connected to third interconnection wiring member 23. Wiring members 4 provided on the back surface 1b side of the top solar cell 1 in solar cell string 12 are connected to second interconnection wiring member 22. Wiring members 4 provided on the front surface 1a side of the bottom solar cell 1 in solar cell string 12 are connected to third interconnection wiring member 23. Wiring members 4 provided on the front surface 1a side of the top solar cell 1 in solar cell string 13 are connected to second interconnection wiring member 22. Wiring members 4 provided on the back surface 1b side of the bottom solar cell 1 in solar cell string 13 are connected to third interconnection wiring member 24.

Wiring members 4 provided on the back surface 1b side of the top solar cell 1 in solar cell string 14 are connected to second interconnection wiring member 25. Wiring members 4 provided on the front surface 1a side of the bottom solar cell 1 in solar cell string 14 are connected to third interconnection wiring member 24. Wiring members 4 provided on the front surface 1a side of the top solar cell 1 in solar cell string 15 are connected to second interconnection wiring member 25. Wiring members 4 provided on the back surface 1b side of the bottom solar cell 1 in solar cell string 15 are connected to third interconnection wiring member 27. Wiring members 4 provided on the back surface 1b side of the top solar cell 1 in solar cell string 16 are connected to first interconnection wiring member 26. Wiring members 4 provided on the front surface 1a side of the bottom solar cell 1 in solar cell string 16 are connected to third interconnection wiring member 27.

As described above, solar cell strings 11 to 16 are electrically connected in series or in parallel to each other through connection to any of first interconnection wiring members 21 and 26, second interconnection wiring members 22 and 25, and third interconnection wiring members 23, 24, and 27.

FIG. 2 is a schematic cross-sectional view taken along the line A-A in FIG. 1. As illustrated in FIG. 2, first bus bar electrode 3a is provided on first principal surface 1a of each of solar cells 1 (1c) and (1d), and second bus bar electrode 3b is provided on second principal surface 1b thereof. First principal surface 1a corresponds to the front surface described above, while second principal surface 1b corresponds to the back surface described above.

As described above, adjacent solar cells 1c and 1d are electrically connected to each other by wiring member 4. To be more specific, one end 4d of wiring member 4 is electrically connected to first bus bar electrode 3a of solar cell 1c, and other end 4c of wiring member 4 is electrically connected to second bus bar electrode 3b of solar cell 1d. First bus bar electrode 3a and one end 4d of wiring member 4 are electrically connected through first resin adhesive layer 32. Second bus bar electrode 3b and other end 4c of wiring member 4 are electrically connected through second resin adhesive layer 31.

As for wiring member 4, a low-resistance material such as copper, silver and aluminum, for example, is used as a core. Wiring member 4 can be formed by silver-plating the surface of the core or by solder plating or the like in consideration of connectivity with the interconnection wiring member, and the like.

In this embodiment, first resin adhesive layer 32 and second resin adhesive layer 31 are resin adhesive layers, each containing a conductive material. First adhesive layer 32 is provided between first bus bar electrode 3a and one end 4d of wiring member 4, and second resin layer 31 is provided between second bus bar electrode 3b and other end 4c of wiring member 4. As for the conductive material, metal particles such as silver, copper, and nickel, for example, and resin particles coated with metal are available. As for resin that forms the resin adhesive layers, epoxy resin, acrylic resin, urethane resin, phenolic resin, silicone resin, a mixture thereof and the like are available, for example.

First protective member 7 is provided on the first principal surface 1a side of solar cell 1, which serves as the light-receiving side. First protective member 7 can be made of glass or the like, for example. Second protective member 8 is provided on the second principal surface 1b side of solar cell 1. Second protective member 8 can be made of resin, for example. Alternatively, second protective member 8 maybe made of a resin sheet in which a metal layer made of aluminum or the like is provided.

Bonding layer 5 is provided between first and second protective members 7 and 8. Bonding layer 5 includes first principal surface 1a side bonding layer 5a and second principal surface 1b side bonding layer 5b. Bonding layer 5 can be made of resin, for example. As for such resin, non-cross-linked resin made of polyethylene, polypropylene or the like, ethylene-vinyl acetate (EVA) copolymer, cross-linked resin made of polyethylene, polypropylene or the like, and the like are available.

As illustrated in FIG. 2, in this embodiment, distance d1 between end portion 32a of first resin adhesive layer 32 on an adjacent side and end portion 1f of solar cell 1d on the adjacent side is longer than distance d2 between end portion 1e of adjacent solar cell 1c and end portion 1f of solar cell 1d. Likewise, distance dl between end portion 31a of second resin adhesive layer 31 on the adjacent side and end portion 1e of solar cell 1c on the adjacent side is longer than distance d2 between end portion 1e of adjacent solar cell 1c and end portion 1f of solar cell 1d.

Therefore, a length of wiring member 4 not fixed by first and second resin adhesive layers 32 and 31 between the adjacent solar cells 1c and 1d is large. Thus, even when wiring member 4 expands or contracts due to temperature change, a large length of wiring member 4 allowed to deform freely can relax stress caused by expansion or contraction. Therefore, cracks, breakage and the like can be inhibited from occurring in wiring member 4 due to temperature change.

### Second Embodiment

FIG. 3 is a schematic cross-sectional view illustrating a solar cell module according to a second embodiment. FIG. 3 corresponds to the schematic cross-sectional view taken along the line A-A in FIG. 1 in the first embodiment.

In this embodiment, distance d3 between end portion 32b of first resin adhesive layer 32 on the side opposite to the adjacent side and end portion 1h of solar cell 1d on the side opposite to the adjacent side is also longer than distance d2 between end portions 1e and 1f of the adjacent solar cells 1c and 1d. Likewise, distance d3 between end portion 31b of second resin adhesive layer 31 on the side opposite to the adjacent side and end portion 1g of solar cell 1c on the side opposite to the adjacent side is also longer than distance d2 between end portions 1e and 1f of the adjacent solar cells 1c and 1d.

As described above, distance d3 is set longer than distance d2, as in the case of distance d1. Thus, in solar cell 1, a region in which first resin adhesive layer 32 is provided on the first principal surface 1a side can be set to extend almost exactly above a region in which second resin adhesive layer 31 is provided on the second principal surface 1b side. As a result, stress can be balanced between the first principal surface 1a side and second principal surface 1b side. Therefore, generation of warpage in the solar cells can be suppressed.

### Third Embodiment

FIG. 4 is a schematic plan view illustrating a solar cell module according to a third embodiment. Here, FIG. 4 illustrates first resin adhesive layer 32 as exposed while omitting wiring member 4 on first resin adhesive layer 32.

In this embodiment, first resin adhesive layer 32 is provided such that end portion 32a of first resin adhesive layer 32 on the adjacent side is positioned between first finger electrode 2a that is the first from end portion 1f of solar cell 1d on the adjacent side and second finger electrode 2b that is the second from end portion 1f of solar cell 1d on the adjacent side. In a conventional case, first resin adhesive layer 32 is provided such that end portion 32a of first resin adhesive layer 32 on the adjacent side reaches first finger electrode 2a, in consideration of current collection efficiency. However, it is found out that, even when end portion 32a of first resin adhesive layer 32 on the adjacent side does not reach first finger electrode 2a as in the case of this embodiment, resistance loss due to wiring member 4 is approximately the same as that when end portion 32a reaches first finger electrode 2a.

Therefore, according to this embodiment, cracks, breakage and the like can be inhibited from occurring in wiring member 4 due to temperature change, without substantially increasing the resistance loss due to wiring member 4.

### Fourth Embodiment

FIG. 5 is a schematic plan view illustrating a solar cell module according to a fourth embodiment. Here, FIG. 5 illustrates first resin adhesive layer 32 as exposed while omitting wiring member 4 on first resin adhesive layer 32.

In this embodiment, first resin adhesive layer 32 is provided such that end portion 32a of first resin adhesive layer 32 on the adjacent side is positioned between second finger electrode 2b that is the second from end portion 1f of solar cell 1d on the adjacent side and third finger electrode 2c that is the third from end portion 1f of solar cell 1d on the adjacent side. As described in the third embodiment, even when end portion 32a of first resin adhesive layer 32 on the adjacent side does not reach first finger electrode 2a, resistance loss due to wiring member 4 is approximately the same as that when end portion 32a reaches first finger electrode 2a. Meanwhile, it is found out that, even when end portion 32a of first resin adhesive layer 32 on the adjacent side does not reach second finger electrode 2b as in the case of this embodiment, resistance loss due to wiring member 4 is approximately the same as that when end portion 32a reaches second finger electrode 2b.

Therefore, according to this embodiment, cracks, breakage and the like can be inhibited from occurring in wiring member 4 due to temperature change, without substantially increasing the resistance loss due to wiring member 4.

<Disposition of Resin Adhesive Layer>

FIG. 6 is a schematic cross-sectional view illustrating a connection state through a resin adhesive layer in the first to fourth embodiments. In the first to fourth embodiments, first resin adhesive layer 32 is disposed between first bus bar electrode 3a and wiring member 4. When the wiring member is bonded to the bus bar electrode using a resin adhesive, the wiring member is generally pressed against and pressure-bonded to the bus bar electrode. Thus, as illustrated in FIG. 6, part of first resin adhesive layer 32 flows out from between wiring member 4 and first bus bar electrode 3a, consequently covering the side surfaces of first bus bar electrode 3a.

As described above, wiring member 4 is pressure-bonded to first bus bar electrode 3a. Thus, there is portion B where first bus bar electrode 3a comes into direct contact with wiring member 4 and is electrically connected thereto. There is also portion A where conductive material 33 contained in first resin adhesive layer 32 is interposed between first bus bar electrode 3a and wiring member 4 for electrical connection therebetween.

FIG. 7 is a schematic cross-sectional view illustrating a connection state through a resin adhesive layer in another embodiment. In this embodiment, resin adhesive layer 35 does not contain conductive material 33. In this embodiment, as illustrated in FIG. 7, first bus bar electrode 3a and wiring member 4 are electrically connected by coming into direct contact with each other.

Note that, in FIGS. 6 and 7, resin adhesive layers 32 and 35 may be provided to extend beyond the edges of wiring member 4 in the width direction.

While, here, the description is given of the case of first resin adhesive layer 32, the same goes for second resin adhesive layer 31.

### EXPLANATION OF REFERENCE NUMERALS

1 solar cell
1a, 1b first and second principal surfaces
1c, 1d solar cell
1e, 1f, 1g, 1h end portion
2 finger electrode
2a to 2c first to third finger electrodes
3a, 3b first and second bus bar electrodes
3 side
4 wiring member
4c other end
4d one end
4e side
5 bonding layer
5a first principal surface side bonding layer
5b second principal surface side bonding layer
7, 8 first and second protective members
10 solar cell module
11 to 16 solar cell strings
21, 26 first interconnection wiring members
22, 25 second interconnection wiring members
23, 24, 27 third interconnection wiring members
31, 32 second and first resin adhesive layers
31a, 31b, 32a, 32d end portions
33 conductive material
35 resin adhesive layer

1. A solar cell module comprising:
solar cells, each including a first bus bar electrode provided on a first principal surface and a second bus bar electrode provided on a second principal surface;
a wiring member connecting the first bus bar electrode of one of adjacent solar cells and the second bus bar electrode of the other of the adjacent solar cells; and
a resin adhesive layer connecting the wiring member and one of the first bus bar electrode and the second bus bar electrode, wherein
a distance in a first direction, in which the adjacent solar cells are arrayed, between an end portion of the resin adhesive layer on the one of the adjacent solar cells and an end portion of the one of the adjacent solar cells is longer than a distance in the first direction between the end portion of the one of the adjacent solar cells and the end portion of the other of the adjacent solar cells.

2. The solar cell module according to claim 1, wherein
finger electrodes extending in a second direction intersecting with the first bus bar electrode or the second bus bar electrode are provided on the first principal surface or the second principal surface, and
the resin adhesive layer is provided such that the end portion of the resin adhesive layer on the one of the adjacent solar cells is positioned between a first finger electrode that is the first from the end portion of the one of the adjacent solar cells, and a second finger electrode that is the second from the end portion of the one of the adjacent solar cells.

3. The solar cell module according to claim 1, wherein
finger electrodes extending in the first direction approximately perpendicular to the first bus bar electrode or the second bus bar electrode are provided on the first principal surface or the second principal surface, and
the resin adhesive layer is provided such that the end portion of the resin adhesive layer on the one of the adjacent solar cells is positioned between a second finger electrode that is the second from the end portion of the one of the adjacent solar cells, and a third finger electrode that is the third from the end portion of the one of the adjacent solar cells.

4. The solar cell module according to claim 1, wherein the resin adhesive layer contains a conductive material.

5. The solar cell module according to claim 4, wherein the conductive adhesive layer is disposed between the wiring member and the first bus bar electrode or the second bus bar electrode.

6. The solar cell module according to claim 1, wherein the resin adhesive layer contains no conductive material.

7. The solar cell module according to claim 6, wherein
the wiring member and the first bus bar electrode or the second bus bar electrode are provided in direct contact with each other, and
the conductive adhesive layer is disposed on a lower surface of the wiring member and a side surface of the first bus bar electrode or the second bus bar electrode so as to be filled therebetween.

8. The solar cell module according to claim 1, wherein a distance between an end portion of the resin adhesive layer on a side opposite to the other of the adjacent solar cells, and an end portion, on the side opposite to the other of the adjacent solar cells, of the one of the adjacent solar cells provided with the resin adhesive layer is longer than the distance between the end portion of one of the adjacent solar cells and the end portion of the other of the adjacent solar cells.
